(19) United States
(12) Patent Application Publication
(10) Pub. No.: US 2007/0138914 A1
(43) Pub. Date: Jun. 21, 2007

(54) WIRING STRUCTURE OF VIBRATOR, AND PIEZOELECTRIC PUMP

(75) Inventors: Jun Ishikawa, Niigata-ken (JP); Satoshi Yamada, Niigata-ken (JP)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(73) Assignee: ALPS ELECTRIC CO., LTD., Ota-ku (JP)

(21) Appl. No.: 11/610,538

(22) Filed: Dec. 14, 2006

(30) Foreign Application Priority Data
Dec. 15, 2005 (JP) 2005-361151

(51) Int. Cl. H01L 41/08

(52) U.S. Cl. 310/328

(57) ABSTRACT

The invention relates a wiring structure of a vibrator and a piezoelectric pump. On the basis of the recognition that it is difficult to obtain sufficient reliability of connecting parts with a conductive adhesive material only while attention is paid to using the conductive adhesive material instead of soldering, a wiring structure is obtained in which a connecting terminal and a film-like electrode are adhered to each other by a conductive adhesive material, and a pressing member which applies a force in a direction in which the connecting terminal is pressed against the film-like electrode is caused to abut on the connecting terminal.

This application claims the benefit of Japanese Patent Application No. 2005-361151, filed on Dec. 15, 2005, the contents of which is incorporated herein by reference.

### BACKGROUND OF THE INVENTION

1. Field of the Invention

The present invention relates to a wiring structure of a vibrator and a piezoelectric pump having the wiring structure.

2. Description of the Related Art

As an apparatus having a vibrator, there is, for example, a piezoelectric pump. In the piezoelectric pump, a pumping action is obtained by forming a variable volume chamber between a flat plate-like piezoelectric vibrator and a housing, and by vibrating the piezoelectric vibrator to change the volume of the variable volume chamber. More specifically, a pair of flow channels connected with the variable volume chamber is provided with a pair of check valves (a check valve which allows flow of fluid to the variable volume chamber and a check valve which allows flow of fluid from the variable volume chamber) having different flow directions. When the volume of the variable volume chamber changes by vibration of the piezoelectric vibrator, a pumping action is obtained from repetition of the operation that one of the pair of check valves is opened and the other valve is closed is repeated. Such a piezoelectric pump is used as, for example, a cooling water circulating pump of a water-cooling notebook computer or a water-cooling desktop computer by making full use of characteristics which can be obtained from a thin pump.

The piezoelectric vibrator is obtained by stacking a piezoelectric body on at least one of the front and back sides of a shim (conductive sheet metal). Polarization characteristics are given to the piezoelectric body in the front and back directions. Thus, the piezoelectric body has a property that, when positive or negative polarity in the same direction as or in a direction opposite to the polarization direction is given between the front and back sides, one surface area increases and the other surface area decreases. For this reason, when positive and negative polarities to be given to the front and back sides of the piezoelectric body are alternately inverted, the cycles that one of the front and back sides expands and the other one shrinks are repeated, and thereby the shim vibrates.

Conventionally, wiring to a piezoelectric vibrator is performed by soldering lead wires to a shim and piezoelectric bodies (film-like electrodes formed on the surfaces thereof) as can be seen from Japanese Unexamined Patent Application Publication Nos. 2006-105027 and 2006-144761. Meanwhile, in a piezoelectric vibrator in which vibrations having an amplitude of 1 mm or less (in the order of 100 μm) are repeated, it was found that poor connection occurs in soldered portions between the film-like electrodes on the piezoelectric vibrator and the lead wires due to long-term use. It is considered that that, since solder is fixed to the film-like electrodes and the lead wires, repetition of fine vibrations causes peel off in the interfaces between the electrodes and lead wires. This problem also applies to a flat plate-like crystal vibrator, etc. having electrodes on the surfaces thereof without being limited to the piezoelectric vibrator.

### SUMMARY OF THE INVENTION

The invention has been made on the basis of the recognition of the above problem, and it is an object of the invention to obtain a wiring structure having high connection reliability and/or durability between a vibrator and lead wires. It is another object of the invention to obtain a piezoelectric pump having high connection reliability and/or durability between a piezoelectric vibrator and lead wires.

The inventors have conceived the invention on the basis of the recognition that it is difficult to obtain sufficient reliability of connecting parts with a conductive adhesive material only while paying attention to using the conductive adhesive material instead of soldering.

Specifically, according to an aspect of the invention, in a wiring structure for electrically connecting a connecting terminal at a tip of a lead wire to a film-like electrode formed on a surface of a vibrator, the connecting terminal and the film-like electrode are adhered to each other by a conductive adhesive material, and a pressing member which applies a force in a direction in which the connecting terminal is pressed against the film-like electrode is caused to abut on the connecting terminal.

As the conductive adhesive material, for example, a conductive double-sided adhesive tape in which conductive metal powder (for example, Ni powder) is mixed into an adhesive layer can be used. A conductive metal foil (Cu foil) double-sided adhesive tape having a metal foil (for example, Cu foil) at the center thereof may be used. These adhesive materials are available from commercialized products. Moreover, the term ‘adhesion’ means a property capable of adhering again even after peel off, and is distinguished from ‘bonding,’ which means having no re-adhesiveness after peel off. The conductive adhesive material as described above appropriately absorbs the vibration of a piezoelectric vibrator by using elasticity of an adhesive layer thereof to prevent concentration of a stress, thereby improving connection reliability between the piezoelectric vibrator and lead wires.

Preferably, materials having excellent elasticity are used for the pressing member. Among these, ethylene-propylene-diene rubber (EPDM) is desirable.

Preferably, an FPC having high flexibility is used as the lead wire.

According to another aspect of the invention, in a piezoelectric pump including a piezoelectric vibrator, a housing which forms a variable volume chamber between the housing and the piezoelectric vibrator, and a lead wire which feeds power to a film-like electrode formed on a surface of the piezoelectric vibrator, and obtaining a pumping action by feeding power to the piezoelectric vibrator via the lead wire to vibrate the piezoelectric vibrator, a connecting terminal at a tip of the lead wire and the film-like electrode are adhered to each other by a conductive adhesive material, and a pressing member which applies a force in a direction in which the connecting terminal is pressed against the film-like electrode is provided on the side of the housing.

In this aspect, the pressing member can be made of a resin material formed integrally with the housing.

As the piezoelectric vibrator, any one of a unimorph-type piezoelectric vibrator in which a piezoelectric body is provided only on either the front side or back side of the middle shim, and a bimorph-type piezoelectric vibrator in which piezoelectric bodies are provided on both the front and back sides can be used. In a more preferred embodiment, it is desirable that a bimorph-type piezoelectric element is used, and the lead wire is an FPC which is connected in the same potential to the film-like electrode formed on each of the surfaces of the front and back piezoelectric bodies.

Moreover, the bimorph-type piezoelectric element formed in a circular shape in plan view is provided at a peripheral edge thereof with a spacer insulating ring made of a rubber material which determines the total thickness of the bimorph-type piezoelectric element. In such a piezoelectric element, when the pressing member is made of the same rubber material as the spacer insulating ring, the design to avoid concentration of a stress (stress is dispersed to both the piezoelectric bodies) is easy, which is preferable.

### BRIEF DESCRIPTION OF THE DRAWINGS

FIG. 1 is a longitudinal sectional view showing the principle of a piezoelectric pump to which a piezoelectric vibrator is to be applied;

FIG. 2 is a schematic exploded perspective view showing an embodiment in which a wiring structure of the invention is applied to a bimorph-type piezoelectric vibrator;

FIG. 3 is an exploded perspective view showing a specific embodiment of a piezoelectric pump having the piezoelectric vibrator to which the wiring structure is applied;

FIG. 4 is a plan view of principal parts of the wiring structure;

FIG. 5 is a sectional view taken along line V-V of FIG. 4; and

FIG. 6 is an enlarged view of principal parts of FIG. 5.

### DESCRIPTION OF THE PREFERRED EMBODIMENT

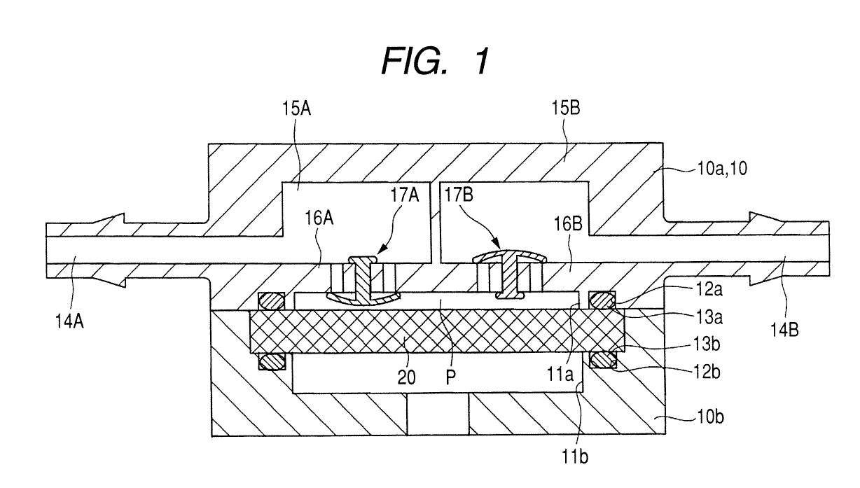

The illustrated embodiment is an embodiment in which the invention is applied to a piezoelectric pump, and the principle of the piezoelectric pump is shown in FIG. 1. A housing 10 is composed of an upper housing 10a and a lower housing 10b. Both the housings 10a and 10b are formed with recessed parts 11a and 11b and seal ring grooves 12a and 12b along the recessed parts 11a and 11b in their facing surfaces, respectively. A piezoelectric vibrator 20 is sandwiched between the upper housing 10a and the lower housing 10b by causing the front and back sides thereof to abut on seal rings 13a and 13b inserted into the seal ring grooves 12a and 12b, respectively, and a variable volume chamber P is formed between the recessed part 11a and the piezoelectric vibrator 20. Although a variable volume chamber is also formed between the recessed part 11b and the piezoelectric vibrator 20, this chamber does not have a pumping action. Although the thickness of the piezoelectric vibrator 20 is drawn exaggeratingly, the actual thickness of the piezoelectric vibrator may be less than 1.5 mm. The shape of the recessed parts 11a and 11b is also a shallow shape along which the piezoelectric vibrator 20 can extend.

In the lower housing 10a, a liquid inlet port 14A and a liquid outlet port 14B are opened. The inlet port 14A communicates with an inlet-side liquid reservoir chamber 15A, and the outlet port 14B communicates with an outlet-side liquid reservoir chamber 15B. A partition wall 16A is located between the inlet-side liquid reservoir chamber 15A and the variable volume chamber P, and a partition wall 16B is located between the outlet-side liquid reservoir chamber 15B and the variable volume chamber P. Umbrellas (e.g., check valves) 17A and 17B are provided in the partition walls 16A and 16B, respectively. The umbrella 17A is a check valve which allows flow of fluid from the inlet port 14A (inlet-side liquid reservoir chamber 15A) to the variable volume chamber P and does not allow the reverse flow of the fluid, and the umbrella 17B is a check valve which allows flow of fluid from the variable volume chamber P to the outlet port 14B (outlet-side liquid reservoir chamber 15B) and does not allow the reverse flow of the fluid.

In the above-described piezoelectric pump, when the piezoelectric vibrator 20 is elastically deformed forward or backward (vibrated), the umbrella 17A is opened and the umbrella 17B is closed in a stroke where the volume of the variable volume chamber P increases. Therefore, liquid flows into the variable volume chamber P from the cooing water inlet port 14A (inlet-side liquid reservoir chamber 15A). On the other hand, the umbrella 17B is opened and the umbrella 17A is closed in a stroke where the volume of the variable volume chamber P decreases. Therefore, liquid flows out to the outlet port 14B (outlet-side liquid reservoir chamber 15B) from the variable volume chamber P. Therefore, a pumping action can be obtained by continuously and elastically deforming (vibrating) the piezoelectric vibrator 20 forward and backward.

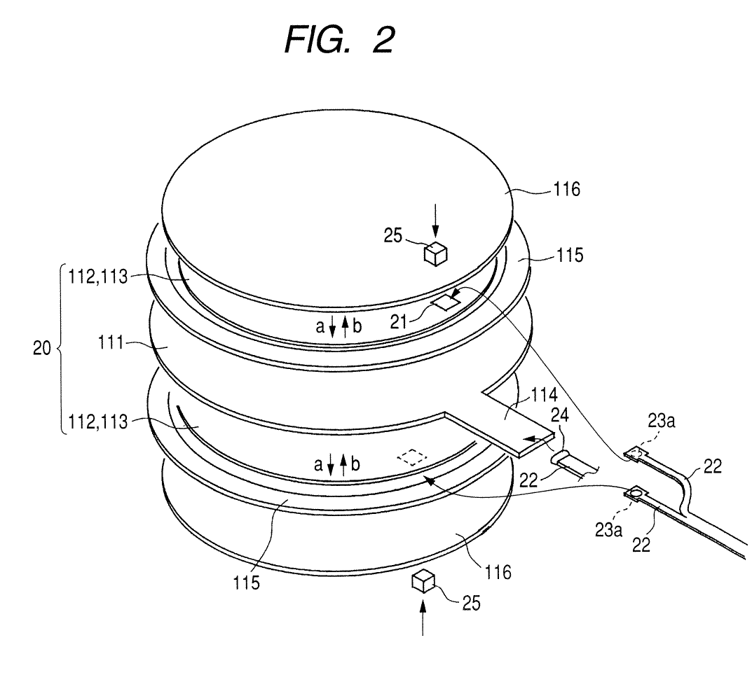

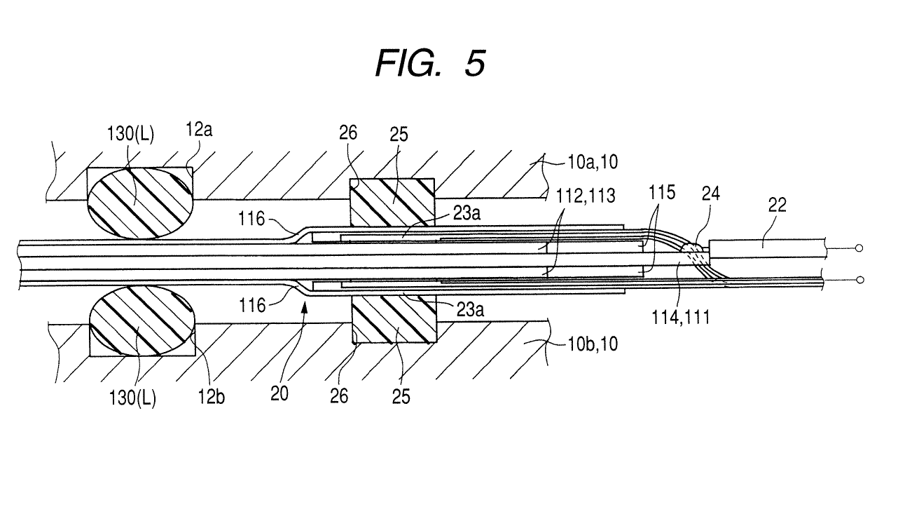

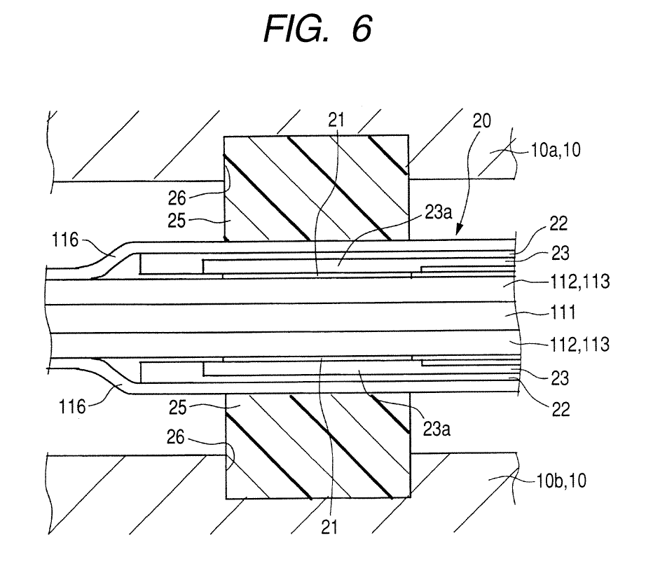

FIGS. 2 to 6 show a more specific embodiment of the piezoelectric pump having the above-described principle of operation. The piezoelectric vibrator 20 of the present embodiment, as shown in FIG. 2 (and FIGS. 5 and 6), is a bimorph-type piezoelectric vibrator including a middle circular shim 111 and piezoelectric bodies 112 formed so as to be stacked on the front and back sides of the shim. The shim 111 is made of a conductive sheet metal material, for example, a 42-alloy sheet metal having a thickness of about 0.2 mm. The piezoelectric bodies 112 are made of, for example, PZT(Pb(Zr, Ti)0₃) having a thickness of about 0.3 mm, and are subjected to polarization treatment in the thickness directions.

This polarization treatment is performed in the same direction on the pair of piezoelectric bodies 112 located on the front and back sides of the shim 111. Specifically, referring to FIG. 2, when the polarization direction of the pair of piezoelectric bodies 112 are indicated by arrows ‘a’ or ‘b’, polarization treatment in the same direction as the thickness direction of the shim 111 is performed. In other words, the pair of front and back piezoelectric bodies which contact the shim show polarization characteristics of different polarities, respectively, and the exposed surfaces of the pair of piezoelectric bodies show different polarities, respectively. If the polarization characteristics of the front and back piezoelectric bodies are made the same direction as such, the displacement of the shim can be increased when positive and negative voltages are alternately applied between the shim, and the exposed surfaces of the pair of front and back piezoelectric bodies.

The surfaces of the pair of piezoelectric bodies 112 on the side of the shim 111 are bonded to the shim 111 so as to be electrically connected to the shim over the entire surface thereof, and film-like electrodes 113 are formed on the entire exposed surfaces of the piezoelectric bodies opposite to the surfaces thereof on the side of the shim 111. Each film-like electrode 113 is formed, for example, by performing printing (e.g., screen baking) with conductive paste (e.g., gold paste) or by sputtering good conductive metal. The shim 111 is formed with a wiring connecting projection 114 which protrudes in a radial direction. By making the film-like electrode 113 of a gold material, it is possible to avoid a migration problem which may be caused when an electrode is made of, for example, a silver material.

Spacer insulating rings 115 which surround the piezoelectric bodies 112 annularly are respectively located above and below the circular shim 111. Each spacer insulating ring 115 defines the total maximum thickness of the piezoelectric vibrator 20, and is made of a rubber material (for example, EPDM).

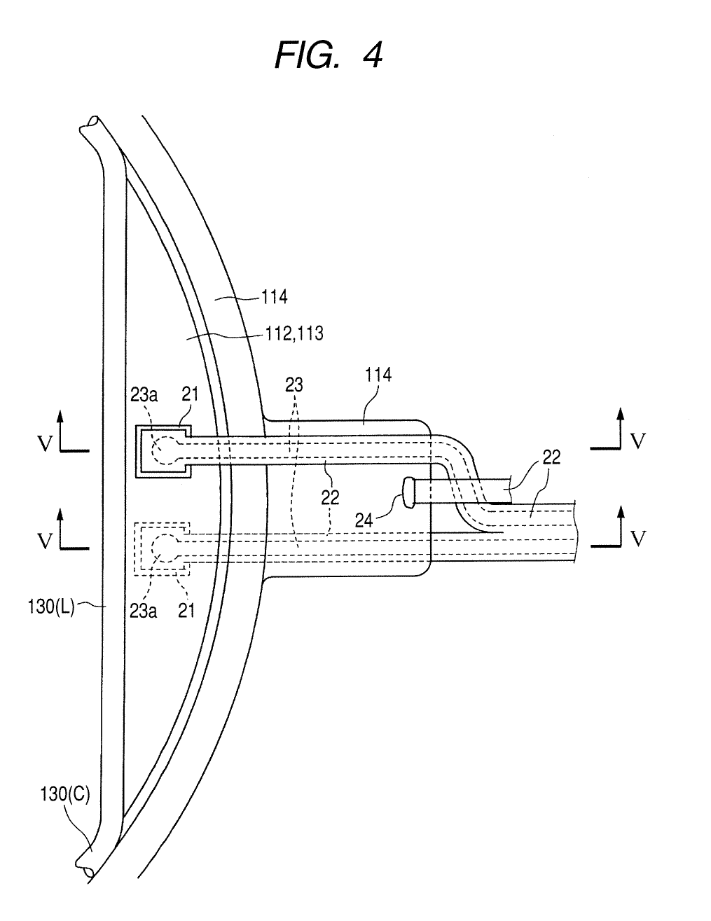

In the above-described circular bimorph-type piezoelectric vibrator 20, an alternating electric field is applied using the shim as one electrode and using the exposed surfaces (film-like electrodes 113) of the pair of piezoelectric bodies 112 as the other common electrodes. In the present embodiment, a connecting terminal 23a at a tip of a lead wire 23 (see, e.g., FIG. 4) within a flexible printed circuit (FPC) 22 is adhered to each piezoelectric body 112 (film-like electrode 113) for wiring thereto by a conductive double-sided adhesive tape (conductive adhesive material) 21. As the conductive double-sided adhesive tape 21, commercialized products (for example, conductive double-sided adhesive tape T4420W made by Sony Chemical Corp. and conductive copper foil double-sided adhesive tapes 8321 and 8322 made by Teraoka Seisakusho KK) can be used. Since the lead wires 23 electrically connected to the front and back piezoelectric bodies 112 (film-like electrodes 113) are electrically connected to each other, they have the same potential. Moreover, a lead wire 24 which makes a pair with the lead wire 23 within the FPC 22 is soldered to the wiring connecting projection 114. The wiring connecting projection 114 may be soldered because it does not vibrate.

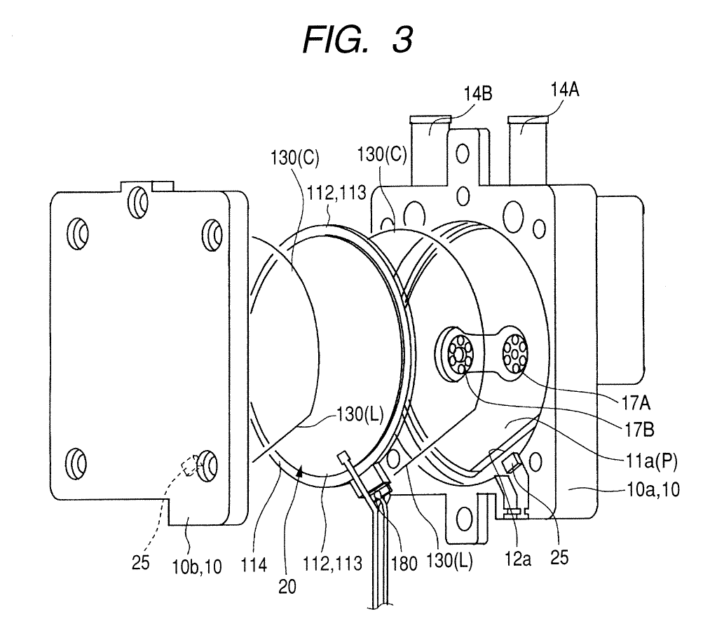

Insulating films 116 (e.g., polyphenylene sulfide (PPS)) (see FIG. 2) are bonded on the surfaces of the piezoelectric vibrator 20 (piezoelectric bodies 112) after the lead wires 23 are adhered thereto by the conductive double-sided adhesive tapes 21 as described above. These insulating films 116 are not drawn in FIGS. 3 and 4.

Pressing rubbers (pressing members) 25 are respectively supported by the housings 10a and 10b correspondingly to the positions where the lead wire connecting terminals 23a and the conductive double-sided adhesive tapes 21 adhere to each other. Specifically, recessed parts 26 are formed in the housings 10a and 10b, respectively, and the pressing rubbers 25 are fitted into the recessed parts 26, respectively. In a state where the housings 10a and 10b are closed, each pressing rubber 25 applies a force in a direction in which the connecting terminal 23a of the lead wire 23 is pressed against the piezoelectric body 112 (film-like electrode 113). The pressing rubbers 25 are made of the same rubber material (for example, EPDM) as the spacer insulating rings 115 of the piezoelectric vibrator 20. The piezoelectric vibrator 20 is supported by the housing 10 with the spacer insulating rings 15 and the pressing rubbers 25. Therefore, since the spacer insulating rings 115 and the pressing rubbers 25 have equal elasticity, a stress can be concentrated on any one of the spacer insulating rings 115 and the pressing rubbers 25, thereby preventing a bad effect from being exerted on the vibration of the piezoelectric vibrator 20. Therefore, it is easy to set stresses occurring in (caused by) the pressing rubbers 25 and the spacer insulating rings 115 in determining various dimensions.

According to the wiring structure of the connecting terminals 23a of the lead wires 23 to the piezoelectric bodies 112 (film-like electrodes 113) of the above-described piezoelectric vibrator 20, since the connecting terminals 23a are adhered by the conductive double-sided adhesive tapes 21, and the connecting terminals 23a always are elastically pressed towards the piezoelectric bodies 112 (conductive double-sided adhesive tapes 21) by the pressing rubbers 25, stable electrical connection can be established. In other words, various dimensions are set such that the connecting terminals 23a always are pressed towards the conductive double-sided adhesive tapes 21 with appropriate forces in consideration of the amplitude of the piezoelectric vibrator 20 and the elasticity of the pressing rubbers 25.

Moreover, in the present embodiment, the piezoelectric vibrator 20 has a circular shape in plan view as its basic shape. In contrast, as shown in FIGS. 3 and 4, the shape of the variable volume chamber P, that is, the recessed parts 11a and 11b of the housing and sealing members 130 (they corresponds to the seal rings 13a and 13b of FIG. 1, and are denoted by single reference numeral 130 in FIGS. 3 to 6) are formed in a non-circular shape (a portion of the piezoelectric vibrator 20 is cut away in an arcuate shape) which is smaller than the piezoelectric vibrator 20, and the connecting terminals 23a are connected to the piezoelectric bodies 112 (film-like electrodes 113) of the piezoelectric vibrator 20 outside the variable volume chamber P.

Specifically, each of the sealing members 130 defining the variable volume chamber P is formed in a modified D-shape having a large circular-arc section 130(C) composed of a partial circle exceeding a semicircle, and a straight section 130(L) connecting both ends of the larger circular-arc section with a straight line. The straight section 130(L) is positioned so as to be outside to the maximum and make the large circular-arc section 130(C) as large as possible within a range in which the areas for wiring to the piezoelectric bodies 112 can be ensured outside the straight section 130(L). By locating the straight section outside to the maximum, a decline in the pump efficiency can be minimized. Moreover, from another viewpoint, the straight section 130(L) is determined in a position where permanent distortion is not left in the straight section when the piezoelectric vibrator 20 vibrates reciprocally. That is, when the above-described circular bimorph-type piezoelectric vibrator 20 is vibrated by applying an alternating electric field between the shim 111 and the exposed surfaces (film-like electrodes 113) of the pair of piezoelectric bodies 112 thereof, the amplitude of the piezoelectric vibrator 20 is the greatest in its center and is reduced toward its peripheral edge. In this connection, the straight section 130(L) is positioned such that permanent distortion is not left in the straight section 130(L). Also, when a lead wire 23 is wired to the outside of the straight section 130(L), it is not necessary to cause the lead wire 23 to intersect the sealing member 130 and there is no case that the sealing member 130 deforms locally. Thus, the durability of the sealing member can be improved. In addition, the amplitude of the piezoelectric vibrator 20 outside the straight section 130(L) is around 100 μm. According to the wiring connection structure of the present embodiment, even if the vibrator experiences such large displacement, a stress caused by the displacement can be absorbed appropriately, thereby ensuring electrical connection between the lead wire 23 and the piezoelectric body 112 (film-like electrode 113).

In the illustrated embodiment, the pressing rubbers 25 made of a rubber material are provided separately from the housings 10a and 10b. However, it is also possible to adopt an aspect in which pressing members are integrally provided in the housings 10a and 10b made of, for example, a resin material. Moreover, the structure of the illustrated piezoelectric vibrator 20 is an example and has the degree of freedom, and the configuration of the umbrellas (e.g., check valves) 17A and 17B does not matter. As the piezoelectric vibrator 20, in addition to a unimorph-type piezoelectric vibrator, a piezoelectric vibrator in which a driving voltage is lowered by a stacked structure of the piezoelectric bodies 112 is known. It is natural that these piezoelectric vibrators can also be used in the invention. Furthermore, the invention can be similarly applied to a flat plate-like vibrator (for example, a crystal vibrator) having film-like electrodes on the surfaces thereof. The pressing members can be provided in fixing members facing such a vibrator, or they can support the fixing members.

According to the invention, it is possible to obtain a wiring structure having high connection reliability between a vibrator and lead wires. When the invention is applied to a wiring structure for a piezoelectric vibrator of a piezoelectric pump, a piezoelectric vibrator with high reliability and long service life is obtained.

1. A wiring structure of a vibrator for electrically connecting a connecting terminal at a tip of a lead wire to a film-like electrode formed on a surface of a vibrator,
wherein the connecting terminal and the film-like electrode are adhered to each other by a conductive adhesive material, and a pressing member which applies a force in a direction in which the connecting terminal is pressed against the film-like electrode is caused to abut on the connecting terminal.

2. The wiring structure of a vibrator according to claim 1,
wherein the conductive adhesive material comprises a conductive double-sided adhesive tape.

3. The wiring structure of a vibrator according to claim 1,
wherein the pressing member comprises a rubber material.

4. The wiring structure of a vibrator according to claim 3,
wherein the rubber material comprises ethylene-propylene-diene rubber.

5. The wiring structure of a vibrator according to claim 1,
wherein the vibrator is a piezoelectric vibrator.

6. The wiring structure of a vibrator according to claim 1,
wherein the lead wire is a flexible printed circuit.

7. A piezoelectric pump comprising a piezoelectric vibrator, a housing which forms a variable volume chamber between the housing and the piezoelectric vibrator, and a lead wire which supplies power to a film-like electrode formed on a surface of the piezoelectric vibrator, and obtaining a pumping action by supplying power to the piezoelectric vibrator via the lead wire to vibrate the piezoelectric vibrator,
wherein a connecting terminal at a tip of the lead wire and the film-like electrode are adhered to each other by a conductive adhesive material, and a pressing member which applies a force in a direction in which the connecting terminal is pressed against the film-like electrode is provided on the side of the housing.

8. The piezoelectric pump according to claim 7,
wherein the pressing member comprises a resin material formed integrally with the housing.

9. The piezoelectric pump according to claim 7,
wherein the pressing member includes a separate member comprising a rubber material, and is supported by the housing.

10. The piezoelectric pump according to claim 7,
wherein the piezoelectric vibrator comprises a bimorph-type piezoelectric element having a middle shim, and piezoelectric bodies on the front and back sides of the shim, and the lead wire comprises a flexible printed circuit which is connected in the same potential to the film-like electrode formed on each of the surfaces of the front and back piezoelectric bodies.

11. The piezoelectric pump according to claim 10,
wherein the bimorph-type piezoelectric element is formed in a circular shape in plain view, and a peripheral edge thereof is provided with a spacer insulating ring comprising a rubber material which determines the total thickness of the bimorph-type piezoelectric element, and the pressing member comprises the same rubber material as the spacer insulating ring.

12. The piezoelectric pump according to claim 9,
wherein the rubber material comprises ethylene-propylene-diene rubber.

13. The piezoelectric pump according to claim 11,
wherein the rubber material comprises ethylene-propylene-diene rubber.

14. The piezoelectric pump according to claim 9,
wherein the rubber material is softer that the housing.

15. The wiring structure of a vibrator according to claim 2,
wherein the double-sided adhesive tape comprises an adhesive layer, and wherein a conductive metal powder is mixed into the adhesive layer.

16. The wiring structure of a vibrator according to claim 2,
wherein the double-sided adhesive tape comprises a conductive metal foil.

17. The piezoelectric pump according to claim 7,
wherein the conductive adhesive material comprises a conductive double-sided adhesive tape.

18. The piezoelectric pump according to claim 17,
wherein the double-sided adhesive tape comprises an adhesive layer, and wherein a conductive metal powder is mixed into the adhesive layer.

19. The piezoelectric pump according to claim 17,
wherein the double-sided adhesive tape comprises a conductive metal foil.

20. The wiring structure of a vibrator according to claim 5,
wherein the piezoelectric vibrator comprises a bimorph-type piezoelectric element.
